(19) United States
(12) Patent Application Publication
(10) Pub. No.: US 2008/0087404 A1
(43) Pub. Date: Apr. 17, 2008

(54) Thermal module

(75) Inventors: Yun-Liang Hsieh, Yangmei Township (TW); Han-Ting Chen, Chudong Township (TW); Jung-Wen Chang, Tao Yuan Shien (TW)

Correspondence Address: RABIN & Berdo, PC, 1101 14TH STREET, NW, SUITE 500, WASHINGTON, DC, 20005, US

(73) Assignee: Quanta Computer Inc., Tao Yuan Shien (TW)

(21) Appl. No.: 11/652,106

(22) Filed: Jan. 11, 2007

(30) Foreign Application Priority Data
Oct. 16, 2006 (TW) 95218270

(51) Int. Cl. H05K 7/20

(52) U.S. Cl. 165/104.26; 361/700; 165/104.33

(57) ABSTRACT

A thermal module includes an evaporator, a metal pipe, a main frame, a heat sink, a wick and a cooling liquid. The evaporator is in touch with a heat source and has a gas outlet and a liquid inlet. Two ends of the metal pipe connect separately with the gas outlet and the liquid inlet of the evaporator to from a closed loop. The metal pipe includes a vapor pipe, a condenser and a liquid pipe. The main frame connects with the wall of the metal pipe near the gas outlet. The heat sink is outside the condenser. The wick is positioned in an inner wall of the evaporator and in the gas outlet. The cooling liquid is in the closed loop.

### RELATED APPLICATIONS

The present application is based on, and claims priority from, Taiwan Application Serial Number 95218270, filed Oct. 16, 2006, the disclosure of which is hereby incorporated by reference herein in its entirety.

### BACKGROUND

1. Field of Invention

The present invention relates to a thermal module. More particularly, the present invention relates to a thermal module of a portable electronics device.

2. Description of Related Art

Along with growth in technology in the electronics industry, the transistor size density is increasing in various chips such as in the central processing units (CPU) and in graphic processing units (GPU). As the speed of the processors increases, the dissipated power and heat energy is also increasing. In order to allow the CPU to operate under stable conditions, effective computer system cooling has become a core design issue, especially for laptop computers with light, slim, and small physical size requirements, it is a highly challenging design task.

FIG. 1 illustrates a 3-dimensional oblique drawing of a conventional thermal module 100. The thermal module 100 is placed within a portable electronics device such as a laptop computer. It is composed of a thermal-conducting pipe 120, a heat sink 130, and a fan 140.

One end of the thermal-conducting pipe 120 touches the heat source 110, the other end touches the heat sink 130. The heat source is usually the CPU, the GPU, the digital signal processor (DSP), or other component with high power dissipation in a portable electronics device. The thermal-conducting pipe 120 may transfer heat produced by the heat source 110 to the heat sink 130. As the fan 140 turns to generate airflow, the heat energy on the heat sink 130 is exchanged with the heat energy in the air, and thus accomplishes the goal of thermal dissipation.

However, due to the limited thermal conductivity of the thermal-conducting pipe in the conventional thermal module 100, there is a limit to the distance between the heat source 110 and the point of thermal dissipation (heat sink 130 and fan 140 in FIG. 1). When the distance between the heat source 110 and the point of thermal dissipation exceeds a certain limit, (i.e. exceeds the distance limit for effective heat transfer in the thermal-conducting pipe 120), the thermal conductivity of the thermal-conducting pipe 120 decreases rapidly. The distance limitation for heat transfer in the thermal-conducting pipe is determined by the structure of the thermal-conducting pipe 120.

FIG. 2 illustrates a cross-section view of thermal-conducting pipe along the pipe axis. The thermal-conducting pipe 120 is a composition of a metal wall 122, a wick 124, and a heat-carrying liquid (not shown). The vaporization end 125 of the thermal-conducting pipe 120 senses the heat from the heat source causing the liquid inside the thermal-conducting pipe 120 to vaporize into steam and enters the cooling end 126. The arrow 127 in FIG. 2 is the direction of the steam movement. After the steam condenses back to liquid form at the cooling end 126, it is sent back to the vaporization end 125 through the wick 124. The arrow 128 is the direction of the liquid movement. Since the vaporized steam and condensed liquid are moving in the opposite directions in the same pipe, the shear force between the liquid-gas interface will affect the moving speed of the liquid and the steam, reducing the thermal conduction efficiency of the thermal-conducting pipe 120. This prevents the steam to be able to quickly carry the heat to the cooling end 126 and the condensed liquid to be able to quickly go back to the vaporization end 125. This leads to over accumulation of heat energy at the vaporization end 125 and results in “dry boiling”. This phenomenon will be even more serious as the length of the thermal-conducting pipe 120 increases, consequently limiting the effective heat transfer distance of the thermal-conducting pipe 120.

### SUMMARY

It is therefore an objective of the present invention to provide a thermal module. The thermal module provides effective thermal dissipation efficiency. Thus, the module may use a smaller fan and heat sink to accomplish the same performance of the conventional thermal module. Not only has the noise in the fan been lowered, portable electronic devices or modules may adapt lighter, slimmer, and more market desirable designs.

In accordance with the foregoing objectives of the present invention, the present invention provides a thermal module. The thermal module comprises an evaporator, a metal pipe, a main frame, a heat sink, a wick and a cooling liquid. The evaporator is in touch with a heat source and has a gas outlet and a liquid inlet. Two ends of the metal pipe connect separately with the gas outlet and the liquid inlet of the evaporator to form a closed loop. The metal pipe includes a vapor pipe, a condenser and a liquid pipe. The vapor pipe is connected with the gas outlet. The liquid pipe is connected with the liquid inlet. The condenser is connected between the vapor pipe and the liquid pipe. The main frame connects with a wall of the vapor pipe of the metal pipe near the gas outlet. The heat sink is outside the condenser. The wick is positioned in an inner wall of the evaporator and in the gas outlet. The cooling liquid is in the closed loop.

From the above mentioned thermal module of the present invention, by connecting the main frame with the metal pipe wall creates a large thermal dissipation surface which lightens the thermal loading on the metal pipe, thus eliminating the dry boiling phenomenon. The main frame uses a highly thermal conductive material such as carbon fiber composite to further enhance the heat dissipation performance of the present invention. In addition, the path of movement of the steam and the liquid in the metal pipe does not overlap in the present invention forming a complete loop. Therefore, the problem of shear force between the liquid-gas interface affecting the liquid and the gas movement as in the conventional thermal-conducting pipe no longer exists. Not only is the thermal conductivity improved, the effective thermal conducting distance is also extended. Thus, the distance between the heat source and the point of thermal dissipation (heat sink and fan) may be extended.

It is to be understood that both the foregoing general description and the following detailed description are by examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 is a 3-dimensional oblique drawing of a conventional thermal module 100;

FIG. 2 is a cross-section view of thermal-conducting pipe along the pipe axis;

FIG. 3 is a 3-dimensional oblique drawing of a thermal module according to one preferred embodiment of this invention;

FIG. 4 is a partial cross-section view of the thermal module in FIG. 3; and

FIG. 5 is a partial enlarged view of the joint between the main frame and the metal pipe wall.

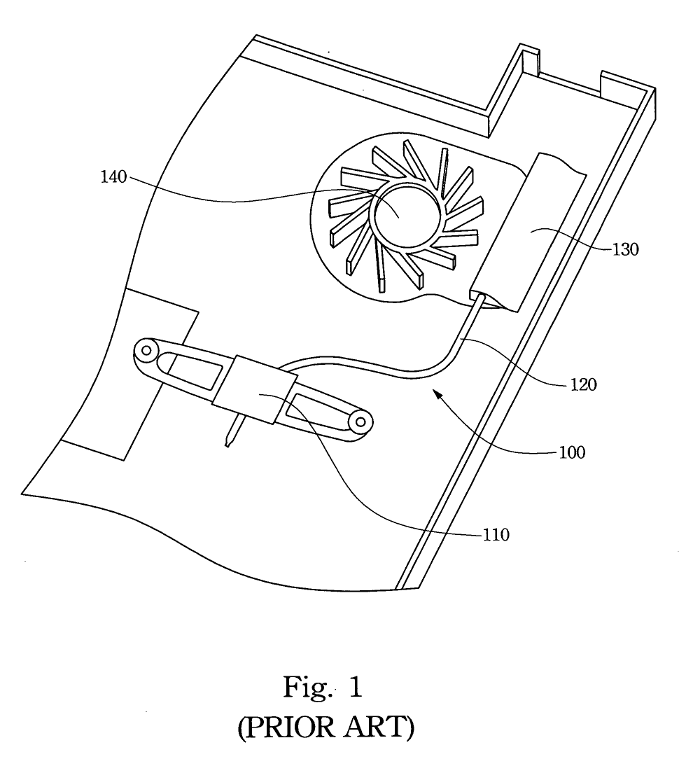

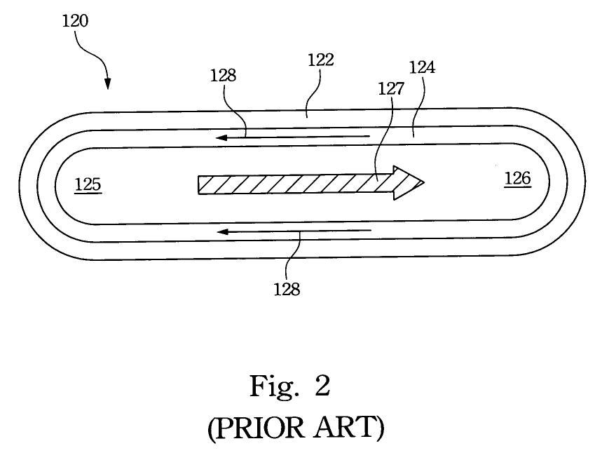

### DESCRIPTION OF THE PREFERRED EMBODIMENTS

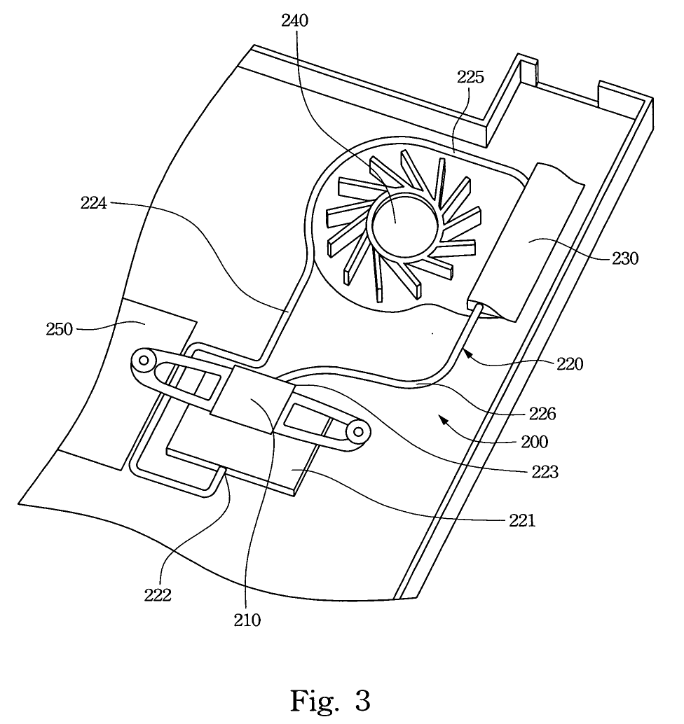

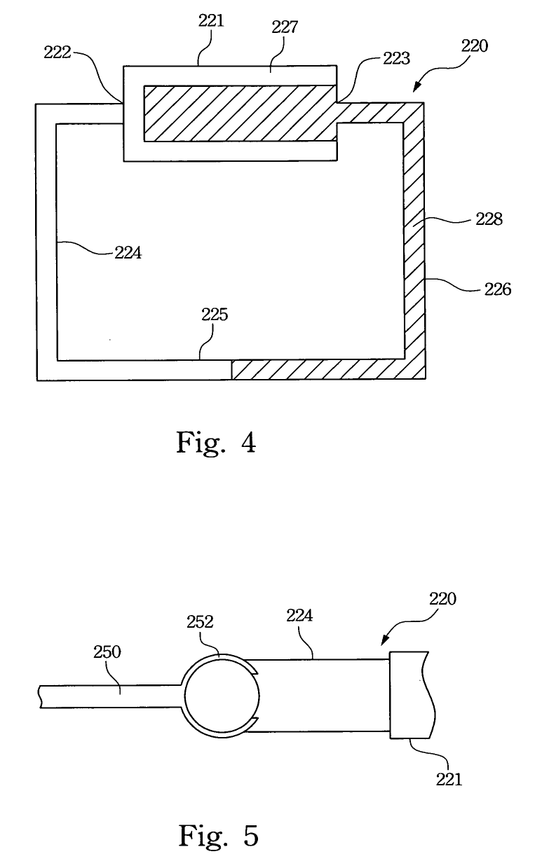

FIG. 3 is a 3-dimensional oblique drawing of a thermal module according to one preferred embodiment of this invention. Since the structural parts of the present invention are positioned in the inside of the thermal module, it is necessary to view the cross-section of the module. Thus, FIG. 4 is a partial cross-sectional view of the thermal module in FIG. 3. Please refer to FIG. 3 and FIG. 4 at the same time. The thermal module 200 of the present invention includes an evaporator 221, a wick 227, a metal pipe 220, a cooling liquid 228, a main frame 250, a heat sink 230 and a fan 240. The evaporator 221 is in touch with a heat source 210 and the evaporator has a gas outlet 222 and a liquid inlet 223. The wick 227 is positioned in the inner wall of the evaporator 221 and in the gas outlet 222. Two ends of the metal pipe 220 are connected separately with the gas outlet 222 and the liquid inlet 223 of the evaporator 221 forming a closed loop. The cooling liquid 228 is in the closed loop. The metal pipe 220 may be divided into three sections according to the difference in functionality: a vapor pipe 224, a condenser 225 and a liquid pipe 226. The vapor pipe 224 is connected with the gas outlet 222; the liquid pipe 226 is connected with the liquid inlet 223. The condenser 225 is connected between the vapor pipe 224 and the liquid pipe 226. The wall of the vapor pipe 224 is connected with the main frame 250. The heat sink 230 is positioned outside of the condenser 225 to carry away the heat from the steam. The fan 240 then is used to cool off the heat sink 230.

The above mentioned main frame 250 is used for structural enhancement. It protects the inner key components from being damaged when the portable electronics device is under collision. The portable electronics device may be a laptop computer. Since portable electronics devices need light, slim, small physical features, thus the main frame 250 usually uses a strong yet lightweight material. It is important to note that the disclosed thermal module is not only applicable in portable electronics devices; it may be applied in electronics modules such as graphics processing modules. In one embodiment of the present invention, in order to raise the thermal dissipation efficiency of the thermal module, the main frame 250 may use a high thermally conductive material such as carbon fiber composite. The thermal conductivity of carbon fiber composite may be as high as 800 W/mk. Carbon fiber composite is strong and light in weight, which complies well with the requirements of a laptop computer.

In this embodiment, the metal pipe 220 is made of copper. In other embodiments, the metal pipe 220 may be made of other materials with good thermal conductivity, such as aluminum. In this embodiment, the diameter of the metal pipe 220 is 3 mm, 6 mm, or 8 mm. The wick 227 is a copper net, groove or multiple sintered holes. The cooling liquid 228 is water.

The main frame 250 and the vapor pipe 224 of metal pipe 220 may be soldered or hooked together. FIG. 5 is a partially enlarged view of the joint between the main frame and the metal pipe wall. In FIG. 5, on one side of the main frame 250 is a C-hook 252. In one embodiment, the C-hook 252 is a ¾ circular ring for the ease of assembly. The size of the C-hook 252 is close to the diameter of the vapor pipe 224 of the metal pipe 220, and is securely attached to the vapor pipe 224 to increase the effective thermal conduction. In order to further increase the effective thermal conduction between the main frame 250 and the vapor pipe 224, a thermal paste may be applied to the contact surface between the C-hook 252 and the vapor pipe 224.

In FIG. 3 and FIG. 4, the cooling liquid 228 is stored in the evaporator 221 and a part of the cooling liquid 228 will enter into the wick 227. Due to the direct contact of the evaporator 221 and the heat source 210, the heat received from the heat source 210 to the evaporator 221 will vaporize the cooling liquid 228 in the wick 227. The volume and the pressure of the cooling liquid 228 will increase after it is vaporized. The vaporized steam will leave the evaporator 221 through the gas outlet 222 into the vapor pipe 224 of the metal pipe 220. Since the wall of the vapor pipe 224 and the main frame 250 are connected, the main frame 250 has a large thermal dissipation surface area, thus part of the heat carried by the steam may be transferred to the main frame 250 to lighten the thermal loading of the metal pipe 220. The steam from the vapor pipe 224 will continue to move towards the condenser 225 and exchange thermal energy with the heat sink 230 on the outside. The steam in the condenser 225 is then condensed back to the cooling liquid 228. The fan 240 near the condenser 225 will guide the air in to carry away the heat on the heat sink 230. Lastly, the cooling liquid 228 leaves the condenser 225 and enters into the liquid pipe 226 through the liquid inlet 223 to go back to the evaporator 221.

The main frame 250 plays a very important role in the thermal module of the present invention. Since the main frame 250 has a large surface area for heat dissipation, it is able to lighten the thermal loading on the metal pipe 220. This will prevent excess heat from accumulating in the metal pipe 220 causing “dry boiling”. If one selects carbon fiber composite as the material used by the main frame 250, it can effectively raise the thermal dissipation efficiency of the thermal module of the present invention in the laptop computer.

In addition, in the thermal module of the present invention, since the steam and the cooling liquid 228 do not move in overlapping paths in the metal pipe 220, therefore shear force between the liquid-gas interface in the conventional thermal-conducting pipe 120 and the problems associated therewith do not exist. Not only does the thermal conductivity improve significantly, the effective thermal conducting distance is increased at the same time. Therefore, the distance between the heat source 210 and the point of thermal dissipation (heat sink 230 and fan 240) may be extended. In comparison with the conventional thermal-conducting pipe 120, the placement of the thermal module of the present invention is more capable of avoiding the predetermined placement of key components and may provide the portable electronics device designer higher design versatility.

Combing the above mentioned, the thermal module of the present invention has excellent thermal dissipation efficiency. A smaller fan and a smaller heat sink may be used to obtain the same thermal results of the conventional thermal module. Not only does the operation noise level of the fan in the portable electronics device decrease, the fan and the heat sink are both smaller and allow lighter, slimmer, and more market desirable portable electronics device designs.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A thermal module, comprising:
an evaporator having a gas outlet and a liquid inlet, wherein the evaporator is in touch with a heat source;
a metal pipe having two ends connected separately with the gas outlet and the liquid inlet to form a closed loop, wherein the metal pipe comprises:
a vapor pipe connected with the gas outlet,
a liquid pipe connected with the liquid inlet, and
a condenser connected between the vapor pipe and the liquid pipe;
a heat sink positioned outside of the condenser;
a wick positioned in an inner wall of the evaporator and in the gas outlet; and
a cooling liquid positioned in the closed loop.

2. The thermal module of claim 1, wherein the thermal module further comprises a main frame connected with an exterior wall of the vapor pipe.

3. The thermal module of claim 2, wherein the main frame provides a C-hook positioned on one side of the main frame to hook onto the exterior wall of the vapor pipe.

4. The thermal module of claim 3, wherein the C-hook is a ¾ circular ring.

5. The thermal module of claim 2, wherein the main frame is hooked onto the exterior wall of the vapor pipe.

6. The thermal module of claim 2, wherein the main frame is soldered onto the exterior wall of the vapor pipe.

7. The thermal module of claim 2, wherein the main frame is made of a carbon fiber composite material.

8. The thermal module of claim 7, wherein the thermal conductivity of the main frame may reach 800 W/mk.

9. The thermal module of claim 1, wherein the thermal module further comprises a fan near the condenser.

10. The thermal module of claim 1, wherein the metal pipe is made of copper.

11. The thermal module of claim 1, wherein the metal pipe is made of aluminum.

12. The thermal module of claim 1, wherein the diameter of the metal pipe is 3 mm, 6 mm, or 8 mm.

13. The thermal module of claim 1, wherein the wick is a copper net, groove or multiple sintered holes.

14. The thermal module of claim 1, wherein the cooling liquid is water.
